(19) United States
(12) Patent Application Publication
(10) Pub. No.: US 2025/0385181 A1
(43) Pub. Date: Dec. 18, 2025

(54) RECESS GATE AND INTERCONNECTOR STRUCTURE AND METHOD FOR PREPARING THE SAME

(71) Applicant: NANYA TECHNOLOGY CORPORATION, NEW TAIPEI CITY (TW)

(72) Inventor: CHIN-LING HUANG, NEW TAIPEI CITY (TW)

(21) Appl. No.: 18/765,141

(22) Filed: Jul. 5, 2024

Related U.S. Application Data
(62) Division of application No. 18/742,145, filed on Jun. 13, 2024.

(51) Int. Cl. H01L 23/528; H01L 23/532

(52) U.S. Cl. CPC H01L 23/5283; H01L 23/53204

(57) ABSTRACT

The present application provides a semiconductor device and a method for preparing the same. The semiconductor device includes a substrate having an active region; a recess gate structure disposed in the substrate and intersecting the active region; a conductive pillar disposed over the substrate and electrically connected to the active region; a landing pad disposed on the conductive pillar and electrically connected to the conductive pillar; and a stack of dielectric layers disposed over the substrate and laterally surrounding the conductive pillar and the landing pad. The semiconductor device also includes a contact structure disposed between the substrate and the conductive pillar, a capacitor plug disposed on the landing pad and electrically connected to the landing pad, and a storage capacitor disposed on the capacitor plug and electrically connected to the capacitor plug.

### CROSS-REFERENCE TO RELATED APPLICATION

This application is a divisional application of U.S. Non-Provisional application Ser. No. 18/742,145 filed Jun. 13, 2024, which is incorporated herein by reference in its entirety.

### TECHNICAL FIELD

The present disclosure relates to a semiconductor device and a method for manufacturing the device, and more particularly, to a semiconductor device having a recess gate and an interconnector structure, and a method for manufacturing the same.

### DISCUSSION OF THE BACKGROUND

The semiconductor industry has developed over the years to create devices with better performance at competitive costs. Such developments have resulted in the continuous reduction of scale of semiconductor devices, which has been realized by numerous and mutually-supportive advances in semiconductor manufacturing processes, along with advances in materials and new device designs.

Dynamic random-access memory (DRAM) is a type of semiconductor device consisting of an array of memory cells, wherein each memory cell includes a field-effect transistor and a capacitor. The field-effect transistor provides access to the capacitor, and the capacitor is configured for data storage. As DRAM continues to be scaled down, space between adjacent memory cells is significantly reduced. As a consequence, parasitic capacitance between adjacent memory cells is increased, and such increases in parasitic capacitance limit operation speeds of a DRAM.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In an aspect of the present disclosure, a memory device is provided. The memory device comprises: a substrate having an active region; a recess gate structure disposed in the substrate and intersecting the active region; a conductive pillar disposed over the substrate and electrically connected to the active region; a landing pad disposed on the conductive pillar and electrically connected to the conductive pillar; and a stack of dielectric layers disposed over the substrate and laterally surrounding the conductive pillar and the landing pad.

In another aspect of the present disclosure, a memory device is provided. The memory device comprises: a first insulating layer concavely disposed in a substrate and comprising a U-shaped cross-sectional profile; a first assisting layer conformally disposed on the first insulating layer and the substrate; a first filler layer disposed on the first assisting layer; a second assisting layer conformally positioned between the first assisting layer and the first filler layer; and a capping dielectric layer disposed on the substrate and covering the first assisting layer and the first filler layer.

In another aspect of the present disclosure, a method for fabricating a semiconductor device is provided. The method comprises: forming an active region in a substrate; forming a recess gate structure in the substrate, wherein the recess gate structure intersects the active region; forming at least one dielectric layer on the substrate; forming a bit line contact in the at least one dielectric layer; forming a bit line over the bit line contact and in an additional dielectric layer; forming a contact structure on the substrate, wherein the contact structure is formed at a side of the recess gate structure, and is electrically connected to the active region; sequentially forming a first conductive layer and a second conductive layer over the substrate, wherein the contact structure is covered by the first and second conductive layers; forming a conductive pillar and a landing pad over the substrate, wherein the conductive pillar overlaps and electrically connects to the contact structure, the landing pad covers and electrically connects to the conductive pillar, and a sidewall of the conductive pillar is laterally recessed from a sidewall of the landing pad; and forming a dielectric layer to laterally surround the conductive pillar and the landing pad.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiments disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. The dimensions of the various features may be arbitrarily increased or reduced for clarity of discussion.

FIG. 1A is a schematic plan view of a semiconductor device in accordance with some embodiments of the present disclosure.

FIG. 1B is a schematic cross-sectional view along a line A-A′ in FIG. 1A.

FIG. 1C is a schematic cross-sectional view along a line B-B′ in FIG. 1A.

FIG. 2 is a flow diagram illustrating a manufacturing method of a semiconductor device in accordance with some embodiments of the present disclosure.

FIGS. 3A to 3N are schematic cross-sectional views of intermediate structures of the semiconductor device in accordance with the method illustrated in FIG. 2.

FIG. 4 is another schematic cross-sectional view of the intermediate structure of the semiconductor device at the stage illustrated in FIG. 3J.

FIG. 5 is a flow diagram illustrating a manufacturing method of a recess gate structure in accordance with step S15 in FIG. 2.

FIGS. 6A to 6N are schematic cross-sectional views of intermediate structures of the semiconductor device in accordance with the method in FIG. 5.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples.

This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

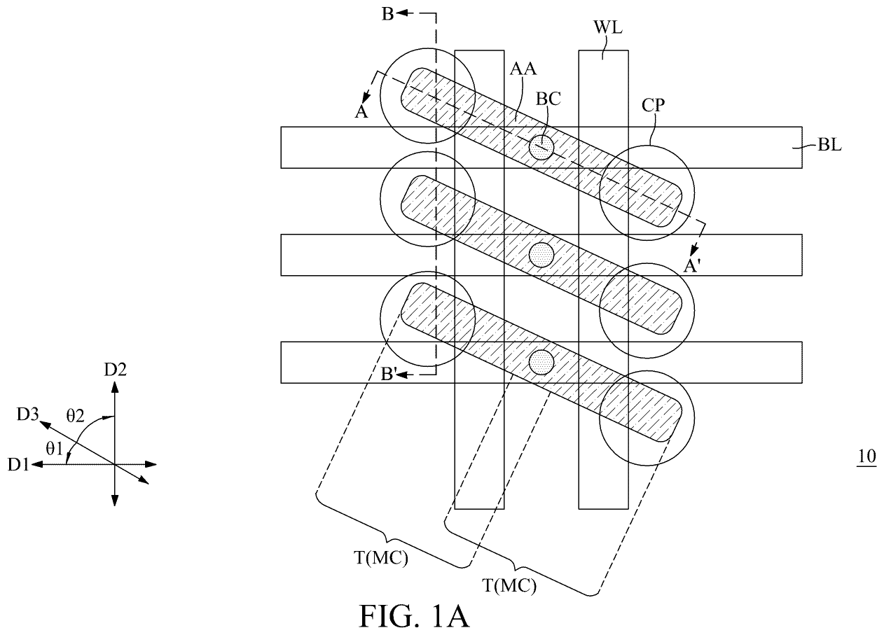

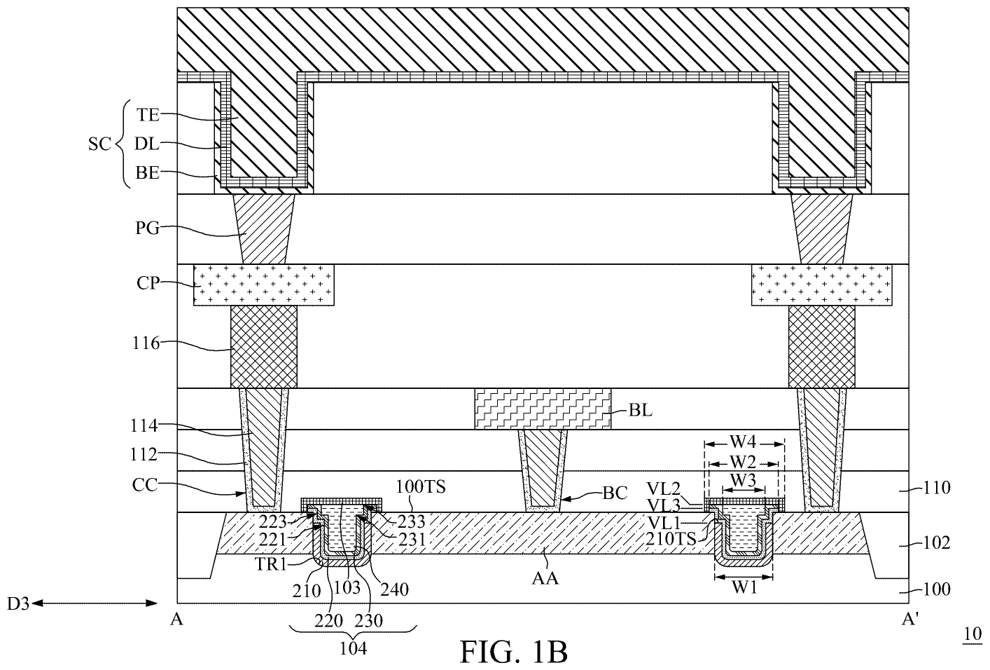

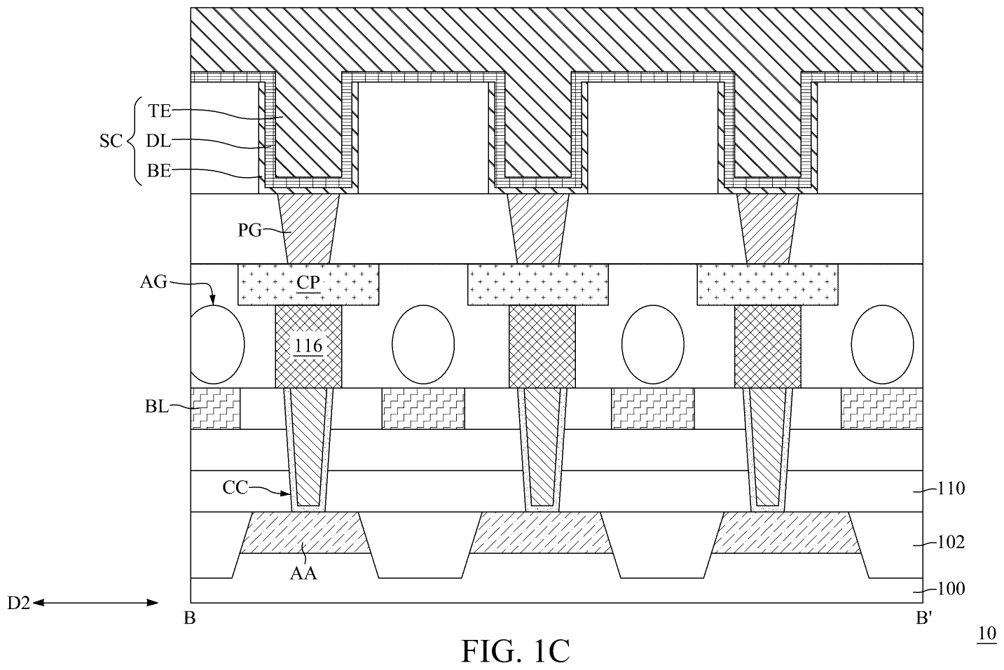

FIG. 1A is a schematic plan view of a semiconductor device 10 in accordance with some embodiments of the present disclosure. FIG. 1B is a schematic cross-sectional view along a line A-A′ in FIG. 1A. FIG. 1C is a schematic cross-sectional view along a line B-B′ in FIG. 1A. It should be noted that some elements shown in FIG. 1B and FIG. 1C (e.g., a substrate 100, an isolation structure 102, interlayer dielectric layers 110, capacitor contacts CC, conductive pillars 116, capacitor plugs PG, air gaps AG and a storage capacitor SC) are omitted from FIG. 1A.

Referring to FIG. 1A, in some embodiments, the semiconductor device 10 is a dynamic random-access memory (DRAM) device. The semiconductor device 10 includes an array of memory cells MC. It should be noted that, for conciseness, only two columns of memory cells MC are depicted in FIG. 1A. The array of memory cells MC includes active regions AA, word lines WL and bit lines BL. Each memory cell MC consists of a field-effect transistor T and the storage capacitor SC (not shown in FIG. 1A) connected to the field-effect transistor T. The field-effect transistor T is defined in the vicinity where one of the active regions AA intersects one of the word lines WL. A portion of the word line WL intersecting the active region AA functions as a gate terminal of the field-effect transistor T, and portions of the active region AA at opposite sides of the word line WL function as source and drain terminals of the field-effect transistor T. One of the source and drain terminals is electrically connected to one of the bit lines BL (e.g., through a bit line contact BC). In addition, other source and drain terminals are electrically connected to the storage capacitor SC (shown in FIG. 1B). In some embodiments, a landing pad CP is formed between the storage capacitor SC and the underlying source terminal or drain terminal of the field-effect transistor T. In addition, in some embodiments, each active region AA is shared by two of the memory cells MC. In such embodiments, each active region AA intersects two of the word lines WL, and the two field-effect transistors T sharing a same active region AA are connected by a common source or drain terminal, which is electrically connected to one of the bit lines BL.

The word lines WL extend along a direction D2, and the bit lines BL extend along a direction D1, wherein the direction D1 and the direction D2 are nonparallel. In some embodiments, the direction D1 is perpendicular to the direction D2. In addition, in some embodiments, the active regions AA extend along a direction D3, wherein the direction D1 and the direction D3 are nonparallel, and the direction D2 and the direction D3 are nonparallel. However, those skilled in the art can recognize that an angle θ1 between the directions D1 and D3, and an angle θ2 between the directions D2 and D3, can be adjusted according to design requirements, and the present disclosure is not limited thereto. In addition, those skilled in the art can recognize that the directions of the components shown in FIG. 1A may be rearranged based on process and design requirements, and the present disclosure is not limited thereto.

Referring to FIGS. 1A and 1B, the active region AA is a region of the substrate 100. The substrate 100 may be a semiconductor wafer or a semiconductor-on-insulator (SOI) wafer. For example, a material of the semiconductor wafer or the SOI wafer may include silicon. In some embodiments, the active region AA of the substrate 100 is a region doped with first conductive type (e.g., n-type) dopants or doped with second conductive type (e.g., p-type) dopants, wherein the second conductive type is complementary to the first conductive type. As discussed above, portions of each active region AA at opposite sides of the intersecting word line WL function as the source and drain terminals of the corresponding field-effect transistor T.

The active regions AA are electrically isolated from one another by the isolation structure 102. In some embodiments, the isolation structure 102 is formed in a recess at a surface of the substrate 100, and is made of an insulating material. In such embodiments, the isolation structure 102, which may also be referred to as a trench isolation structure, extends from the surface of the substrate 100 into the substrate 100. A depth of the isolation structure 102 may be greater than a depth of the active region AA, and the active regions AA are laterally separated from one another by the isolation structure 102. It should be noted that the isolation structure 102 extends between the active regions AA, and what appear in FIG. 1B to be multiple portions of the isolation structure 102 may actually be connected to one another.

In some embodiments, the word lines WL are formed in recess gate structures 104, respectively. The recess gate structures 104 extend along the direction D2 (shown in FIG. 1A) and intersect the active regions AA (as shown in FIG. 1B). In some embodiments, each active region AA intersects two of the recess gate structures 104. As shown in FIG. 1B, the recess gate structures 104 are respectively deposited in a recess TR1 at the surface of the substrate 100. A depth of the recess TR1 may be greater than the depth of the active region AA and may be greater than, equal to, or less than the depth of the isolation structure 102. In some embodiments, the recess gate structures 104 respectively include a first insulating layer 210, a first assisting layer 220, a second assisting layer 230, a first filler layer 240 (i.e., the word line WL) and a capping dielectric layer 103. The first insulating layer 210 may be concavely disposed in the substrate 100, and may conformally cover a surface of the recess TR1 and comprise a U-shaped cross-sectional profile.

The first assisting layer 220 may be conformally deposed on the first insulating layer 210 and the substrate 100. The second assisting layer 230 may be conformally disposed on the first assisting layer 220. The first filler layer 240 may be deposited in the recess TR1 and disposed on the second assisting layer 230, wherein the first filler layer 240 comprises a T-shaped cross-sectional profile. The capping dielectric layer 103 may be disposed on the substrate 100 and may cover the first assisting layer 220, the second assisting layer 230 and the first filler layer 240. A top surface 210TS of the first insulating layer 210 is at a vertical level VL1 lower than a top surface 100TS of the substrate 100. The first assisting layer 220 comprises a first step portion 221 and a second step portion 223, wherein the first step portion 221 of the first assisting layer 220 is disposed adjacent to the top surface 210TS of the first insulating layer 210, and the second step portion 223 of the first assisting layer 220 is disposed adjacent to the top surface 100TS of the substrate 100.

In some embodiments, the first insulating layer 210 is formed of high-k materials, an oxide, a nitride, an oxynitride, or a combination thereof. The first assisting layer 220 is formed of manganese. In some embodiments, the first assisting layer 220 may be formed by atomic layer deposition or other applicable deposition processes. In some embodiments, the second assisting layer 230 is formed of titanium silicon nitride. The first filler layer 240 may be formed of aluminum, tungsten, copper, or a combination thereof. In some embodiments, the capping dielectric layer 103 may be formed of silicon oxide, silicon nitride, silicon oxynitride, silicon nitride oxide, or other applicable insulating materials.

A stack of the interlayer dielectric layers 110 is formed over the substrate 100, and the active regions AA, the isolation structure 102 and the recess gate structures 104 are covered by the interlayer dielectric layers 110. In addition, the bit line contacts BC and the capacitor contacts CC are formed in the stack of interlayer dielectric layers 110. The bit line contacts BC and the capacitor contacts CC respectively penetrate through bottommost ones of the interlayer dielectric layers 110, to establish electrical contact with the active regions AA. Each of the bit line contacts BC may be connected to a portion of the corresponding active region AA that is located between two of the word lines WL intersecting such active region AA. In other words, the bit line contacts BC are electrically connected to the common source/drain terminals of the transistors T (as shown in FIG. 1A). In contrast, the capacitor contacts CC are electrically connected to another source/drain terminal of each transistor T, such that each of the word lines WL is located between one of the bit line contacts BC and one of the capacitor contacts CC. The bit line contacts BC are electrically connected to the bit lines BL, while the capacitor contacts CC are electrically connected to storage capacitors (e.g., the storage capacitors SC, described below). In some embodiments, the bit lines BL are formed at a height lower than a height of the storage capacitors SC. In such embodiments, the bit line contacts BC may be shorter than the capacitor contacts CC, and top ends of the bit line contacts BC may be lower than top ends of the capacitor contacts CC. For example, the bit line contacts BC penetrate through two bottommost of the interlayer dielectric layers 110, while the capacitor contacts CC penetrate through three bottommost of the interlayer dielectric layers 110. Furthermore, in some embodiments, each of the bit line contacts BC and the capacitor contacts CC includes a conductive column 114 and a barrier layer 112 covering a sidewall and a bottom surface of the conductive column 114.

In some embodiments, the interlayer dielectric layers 110 may be made of a dielectric material. For example, the dielectric material may include silicon nitride, silicon oxide, silicon oxynitride, undoped silica glass, borosilica glass, phosphosilica glass, borophosphosilica glass, or a combination thereof. In addition, the conductive columns 114 of the bit line contacts BC and the capacitor contacts CC may be made of aluminum, copper, tungsten, cobalt, another suitable metal or a metal alloy, and the barrier layer 112 of the bit line contacts BC and the capacitor contacts CC may be made of, for example, tungsten nitride.

The bit lines BL cover and electrically connect to the bit line contacts BC. Although not shown, each of the bit lines BL may cover the respective bit line contact BC electrically connected to a row of transistors T, and each of the bit lines BL may extend along the direction D1. As shown in FIG. 1B, the bit lines BL may be formed in one of the interlayer dielectric layers 110 above the bit line contacts BC. In some embodiments, topmost portions of the capacitor contacts CC and the bit lines BL are located in a same interlayer dielectric layer 110. In such embodiments, top surfaces of the bit lines BL may be substantially coplanar with top surfaces of the capacitor contacts CC. In alternative embodiments, the bit line contacts BC are much shorter than the capacitor contacts CC, and the top surfaces of the bit lines BL may be lower than the top surfaces of the capacitor contacts CC. In addition, in some embodiments, the bit lines BL are made of a conductive material. For example, the conductive material may include aluminum, copper, tungsten, cobalt, other suitable metals, or metal alloys.

Referring to FIGS. 1B and 1C, the conductive pillars 116 and the landing pads CP are disposed on the capacitor contacts CC. Each of the conductive pillars 116 stands on one of the capacitor contacts CC, and is covered by one of the landing pads CP. A vertical height of the conductive pillar 116 may be greater than a vertical height (or a thickness) of the landing pad CP. In some embodiments, a sidewall of each conductive pillar 116 is laterally recessed from a sidewall of the overlying landing pad CP. In such embodiments, each conductive pillar 116 has a footprint area smaller than a footprint area of the corresponding landing pad CP. In addition, the conductive pillars 116 may be entirely overlapped by the landing pads CP. The conductive pillars 116 and the landing pads CP may be formed in a same interlayer dielectric layer 110 covering the capacitor contacts CC. In embodiments where the top surfaces of the bit lines BL are coplanar with or lower than the top surfaces of the capacitor contacts CC, the bit lines BL are also disposed below the conductive pillars 116 and the landing pads CP. As shown in FIG. 1C, a distance between adjacent landing pads CP is less than a distance between adjacent conductive pillars 116. As a consequence, when the interlayer dielectric layer 110 is deposited in the spaces between the adjacent landing pads CP and the spaces between the adjacent conductive pillars 116, the smaller spaces between the adjacent landing pads CP may be filled sooner than the larger spaces between the adjacent conductive pillars 116. Accordingly, air gaps AG may be formed and sealed in the larger spaces (i.e., in the spaces between the adjacent conductive pillars 116). In some embodiments, the air gaps AG do not expose sidewalls of the conductive pillars 116, and do not expose the top surfaces of the underlying bit lines BL. However, in alternative embodiments, at least some portions of the sidewalls of the conductive pillars 116 and/or at least some portions of the top surfaces of the bit lines BL are exposed by the air gaps AG. In addition, in certain embodiments, top ends of the air gaps AG may extend to the spaces between the landing pads CP. Further, although the air gaps AG are depicted as oval shapes in FIG. 1C, the air gaps AG can be formed into other shapes, and the present disclosure is not limited thereto.

The landing pads CP and the conductive pillars 116 are made of different conductive materials. In some embodiments, a resistivity of the conductive material for forming the landing pads CP is less than a resistivity of the conductive material for forming the conductive pillars 116, and the conductive material for forming the conductive pillars 116 has a sufficient etch resistance compared to that of the conductive material.

The landing pads CP and the conductive pillars 116 may each be formed by an etching process. In some embodiments, the landing pads CP may be formed by a first etching process. In some embodiments, the conductive pillars 116 may be formed by a second etching process that follows the first etching process.

In some embodiments, each of the capacitor plugs PG stands on one of the landing pads CP. The capacitor plugs PG may be formed in one of the interlayer dielectric layers 110 covering the landing pads CP. Since each of the landing pads CP has a footprint area greater than a footprint area of the underlying conductive pillar 116, connection between the capacitor plugs PG and the conductive pillars 116 can be established even when the capacitor plugs PG are offset from the conductive pillars 116. In other words, due to the landing pads CP, electrical connection between the capacitor plugs PG and the conductive pillars 116 can be ensured. In addition, as described above, the air gaps AG can be formed as a result of disposing the landing pads CP. The capacitor plugs PG are made of a conductive material. For example, such conductive material may include aluminum, copper, tungsten, cobalt, and other suitable metals or metal alloys.

Each of the storage capacitors SC is disposed on and electrically connected to one of the capacitor plugs PG. In some embodiments, the interlayer dielectric layer 110 above the capacitor plugs PG may have openings overlapping the capacitor plugs PG, and the storage capacitor SC may fill the openings and may cover a top surface of the interlayer dielectric layer 110. The storage capacitors SC may include bottom electrodes BE, a dielectric layer DL and a top electrode TE. The bottom electrodes BE conformally cover a sidewall and a bottom surface of each opening in the interlayer dielectric layer 110 above the capacitor plugs PG. The bottom electrodes BE are separated from one another, and are respectively in electrical connection with one of the capacitor plugs PG. The dielectric layer DL conformally covers surfaces of the bottom electrodes BE and the top surface of the interlayer dielectric layer 110 in which the bottom electrodes BE are disposed. The top electrode TE fills the openings of the aforementioned interlayer dielectric layer 110 and may extend onto a topmost surface of the interlayer dielectric layer 110. In the embodiments described above, the dielectric layer DL and the top electrode TE are shared by the storage capacitors SC (i.e., the dielectric layer DL and the top electrode TE extend across multiple storage capacitors SC). The bottom electrodes BE and the top electrode TE are respectively made of a conductive material, while the dielectric layer DL may be made of a high-k dielectric material. For example, the conductive material for forming the bottom electrodes BE may include doped polysilicon, metal silicide, aluminum, copper or tungsten, while the conductive material for forming the top electrode TE may include doped polysilicon, copper, or aluminum. In addition, the high-k dielectric material for forming the dielectric layer DL may include barium strontium titanate, lead zirconium titanate, titanium oxide, aluminum oxide, hafnium oxide, yttrium oxide, zirconium oxide or the like.

Referring to FIGS. 1A to 1C, in some embodiments, the storage capacitors SC are electrically connected to the transistors T through the capacitor plugs PG, the landing pads CP, the conductive pillars 116 and the capacitor contacts CC. As shown in FIGS. 1A and 1C, as a size of each memory cell MC decreases, a distance between adjacent memory cells MC along the direction D2 may also be reduced. As a consequence, parasitic capacitance between adjacent conductive pillars 116 is increased, and such an increase in parasitic capacitance results in greater resistance-capacitance (RC) delay of the semiconductor device 10. As described above, by forming the landing pads CP to each be larger than the underlying conductive pillar 116, the air gaps AG can be formed between adjacent conductive pillars 116. Air sealed in the air gaps AG has a dielectric constant of approximately 1, which is significantly less than a dielectric constant of a solid dielectric material (i.e., the dielectric material for forming the interlayer dielectric layers 110). Therefore, the parasitic capacitance between the conductive pillars 116 can be reduced by the formation of the air gaps AG, and the RC delay of the semiconductor device 10 can be effectively reduced.

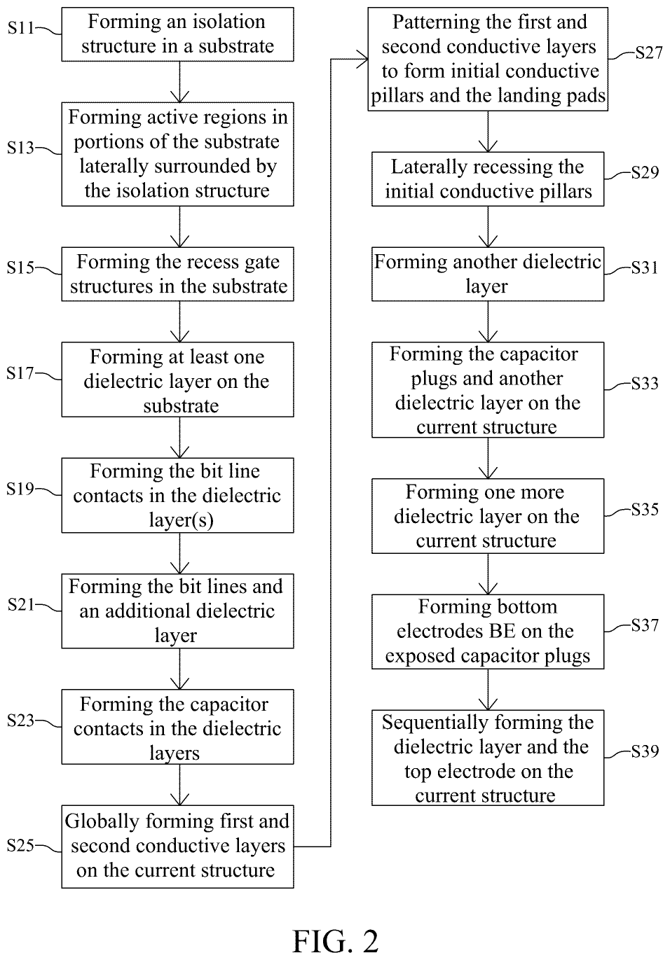

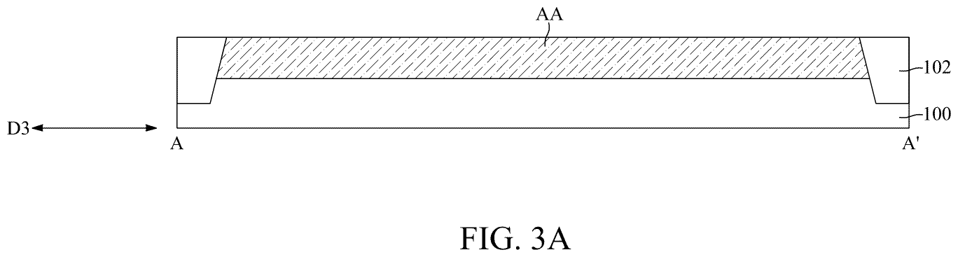

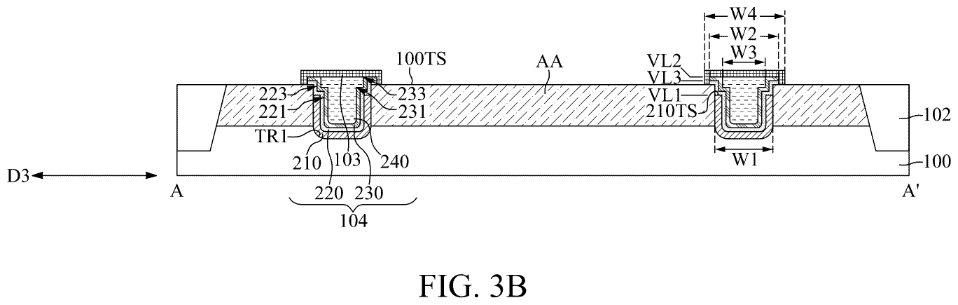

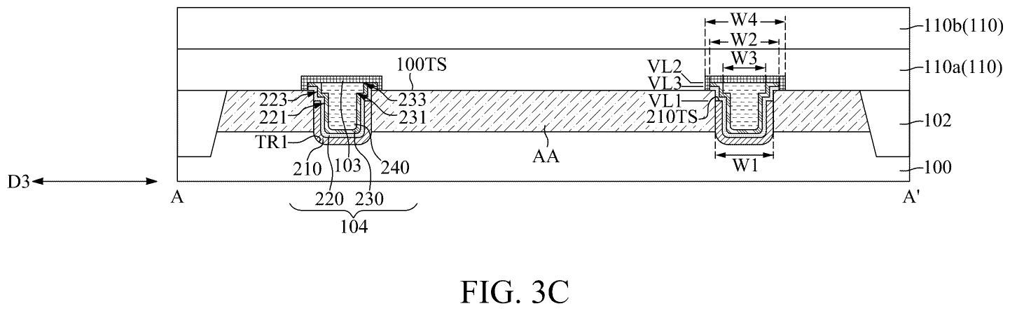

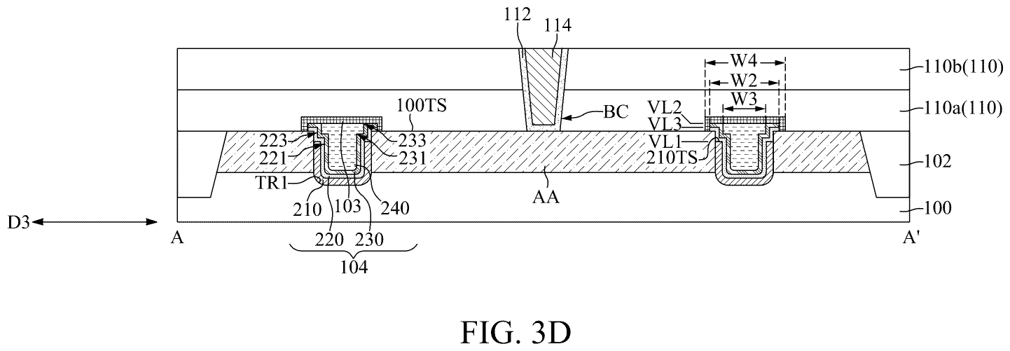

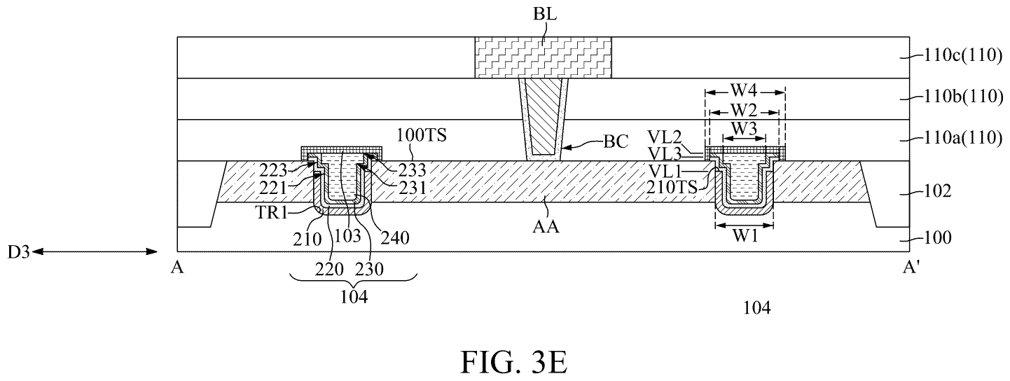

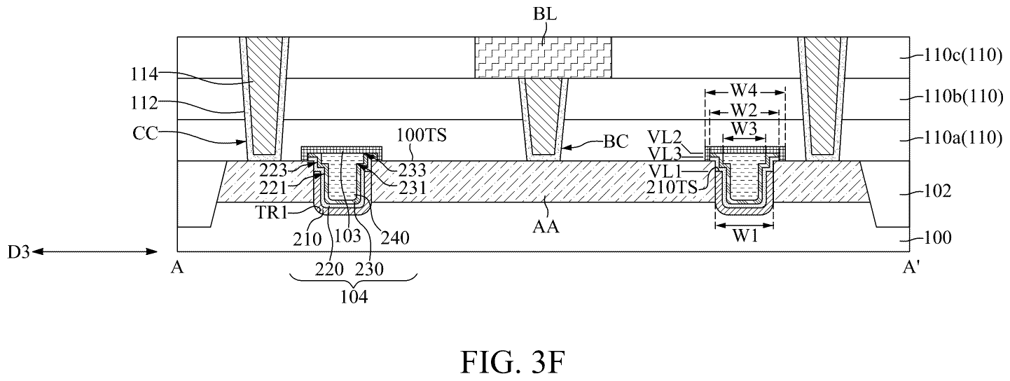

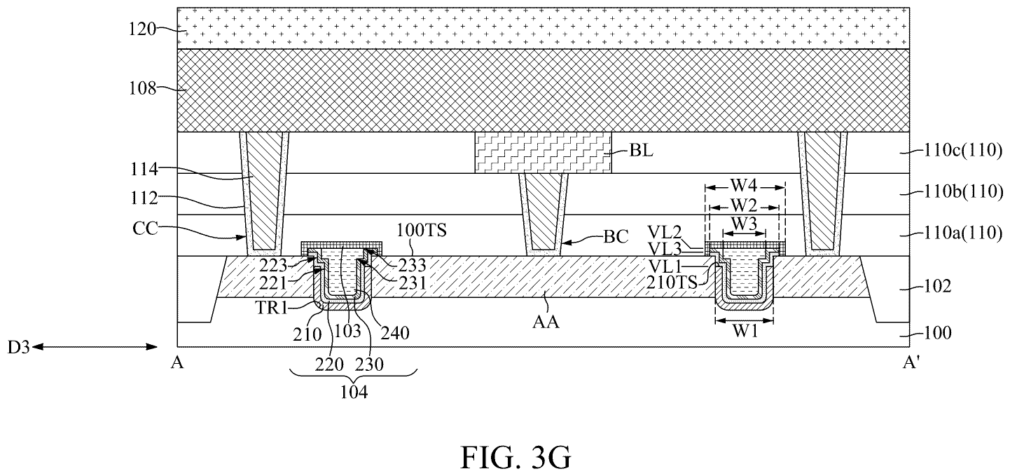

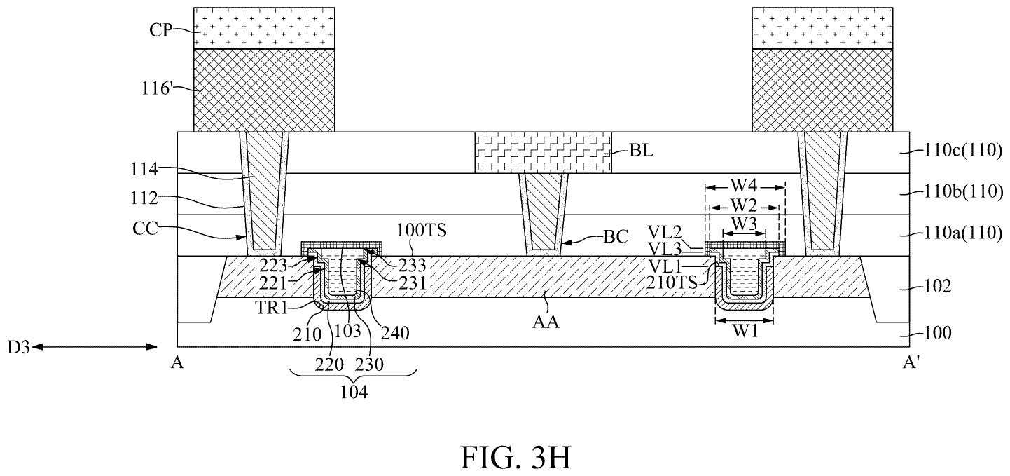

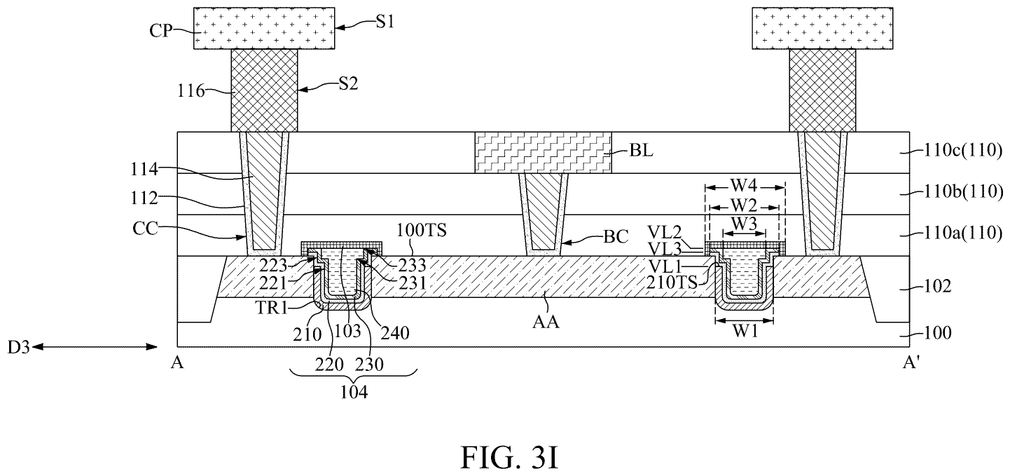

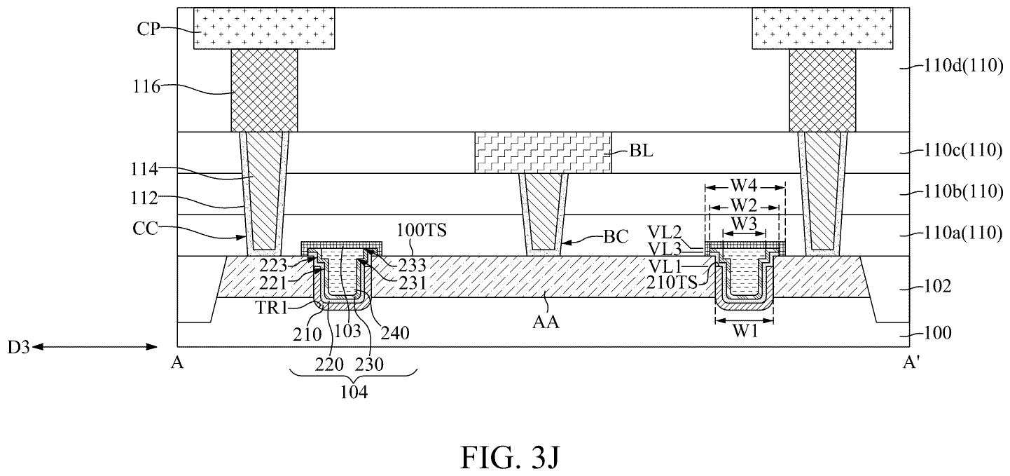

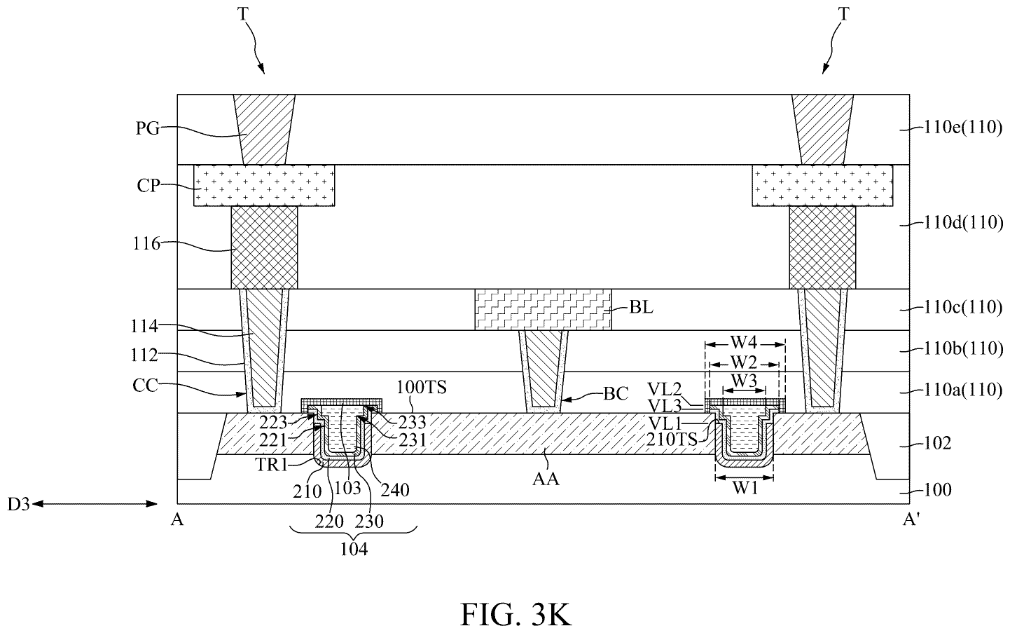

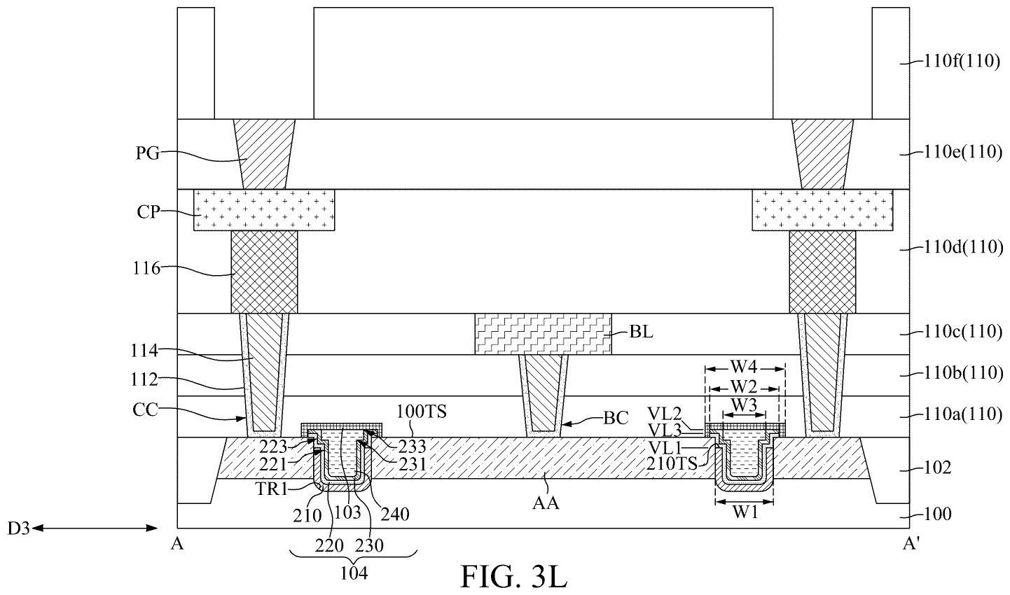

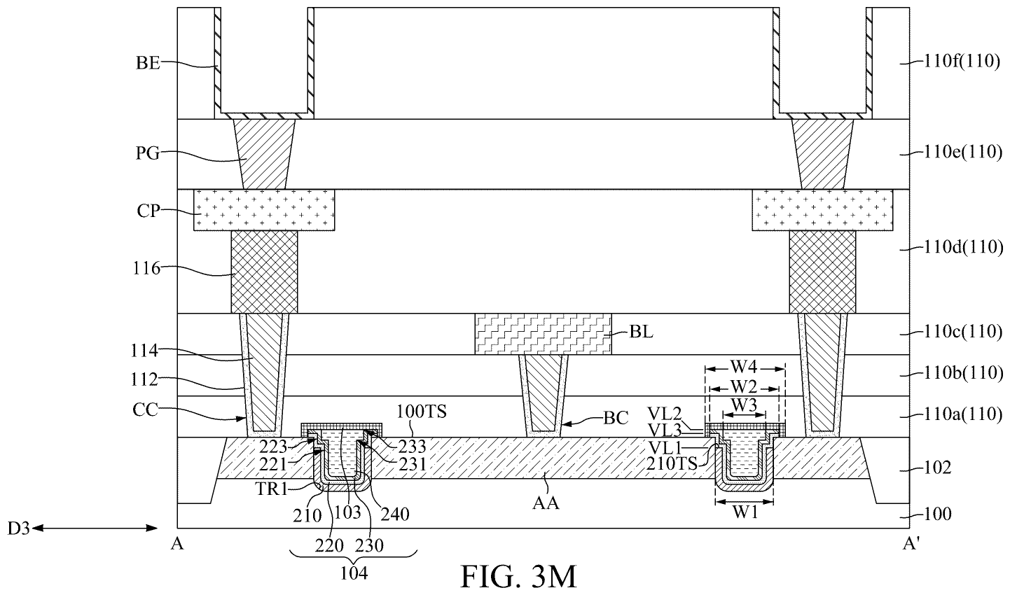

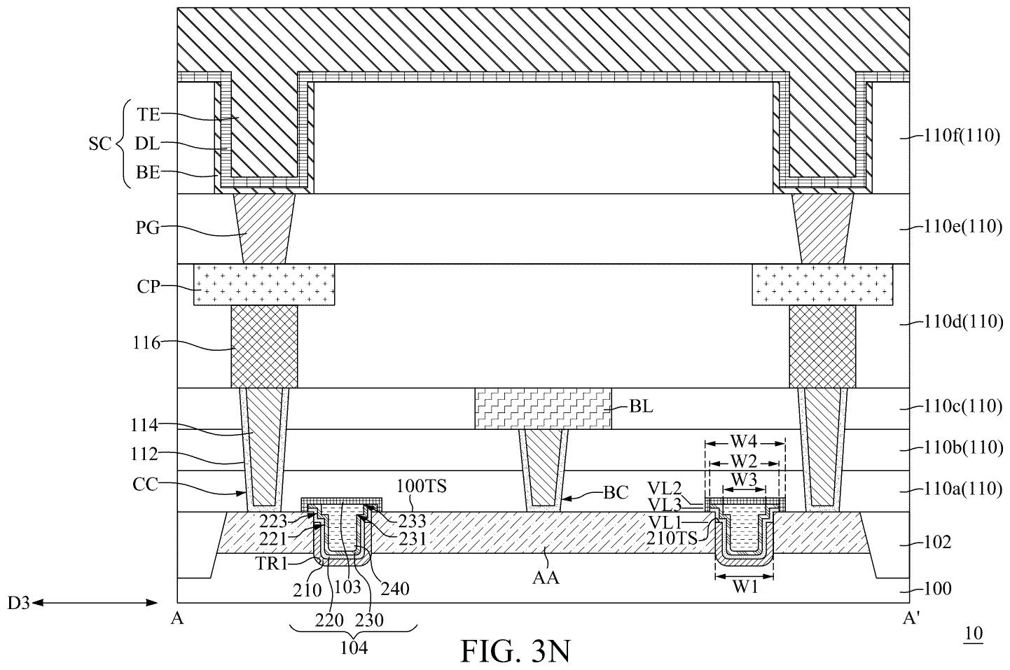

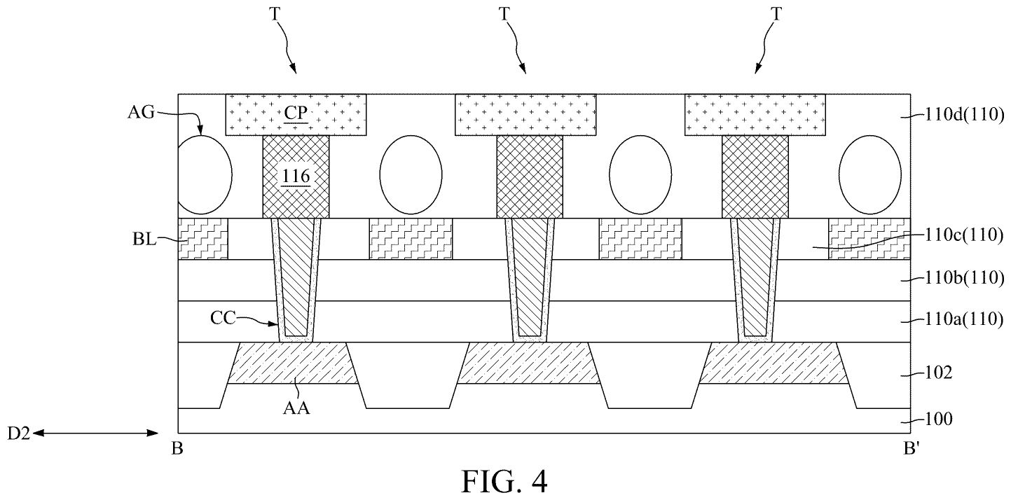

FIG. 2 is a flow diagram illustrating a manufacturing method of the memory device 10 shown in FIGS. 1A to 1C. FIGS. 3A to FIG. 3N are schematic cross-sectional views along one of the active regions AA (e.g., along the line A-A′ shown in FIG. 1A) in structures at various stages during the manufacturing of the memory device 10. FIG. 4 is another schematic cross-sectional view (along the line B-B′ shown in FIG. 1B) of the structure at the stage illustrated in FIG. 3J.

Referring to FIGS. 2 and 3A, step S11 is performed, wherein the isolation structure 102 is formed in the substrate 100. The isolation structure 102 defines portions of the substrate 100 to be formed as the active regions AA. In some embodiments, the isolation structure 102 is a trench isolation structure. In such embodiments, a method for forming the isolation structure 102 may include forming a trench at a surface of the substrate 100 by a lithography process and an etching process (e.g., an anisotropic etching process), and depositing an insulating material into the trench. Next, a planarization process may be performed to remove portions of the insulating material above the substrate 10. A remaining portion of the insulating material forms the isolation structure 102. For example, the planarization process described in the present disclosure may include a chemical mechanical polishing (CMP) process, an etching process, or a combination thereof.

Next, step S13 is performed, wherein the active regions AA are formed in the portions of the substrate 100 laterally surrounded by the isolation structure 102. In some embodiments, the active regions AA are formed by an ion implantation process, during which n-type or p-type dopants are implanted into the substrate 100. In such embodiments, the isolation structure 102 may function as a mask during the ion implantation process.

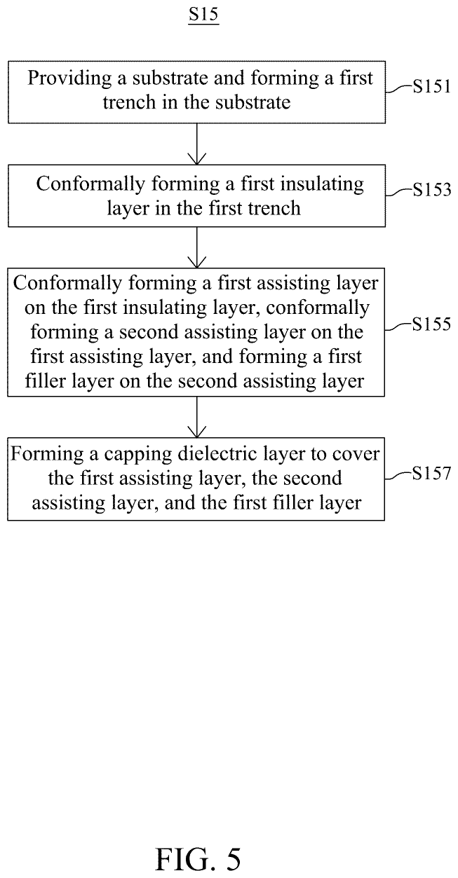

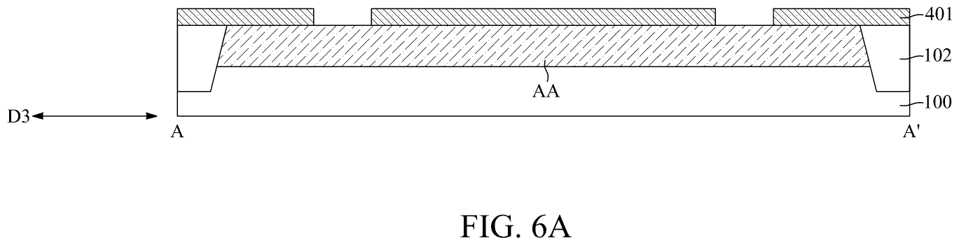

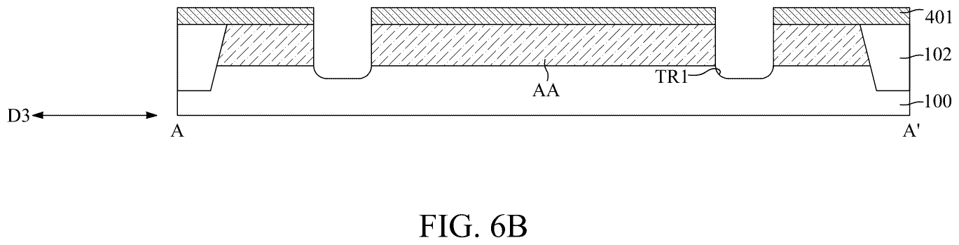

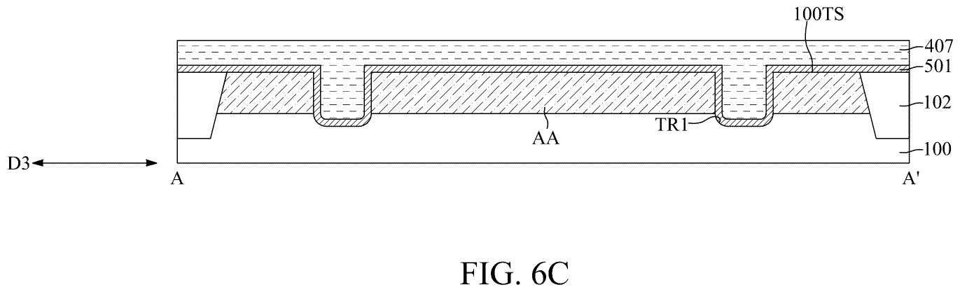

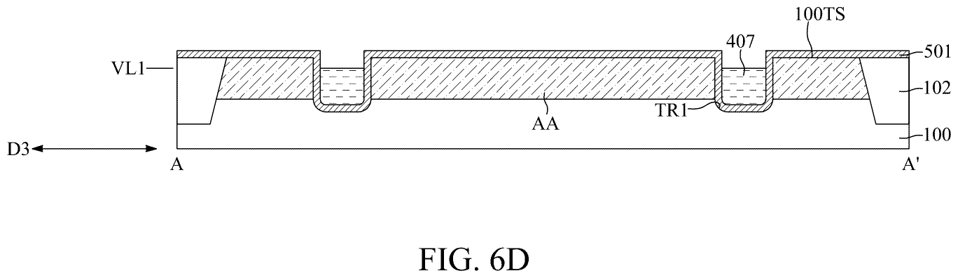

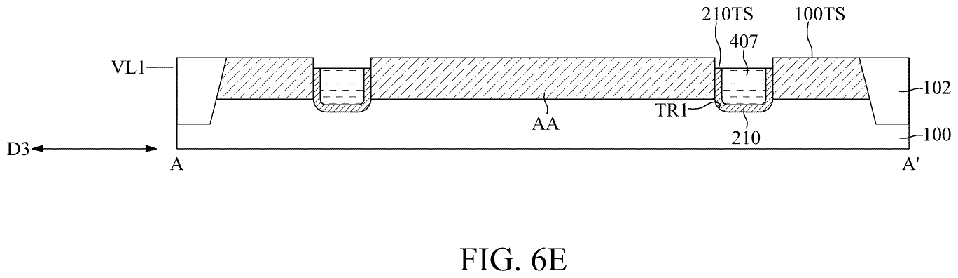

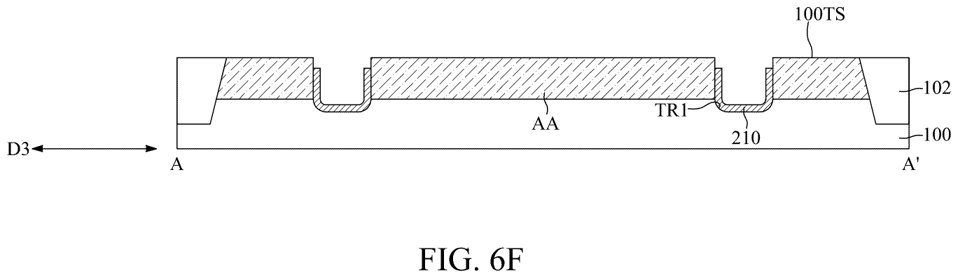

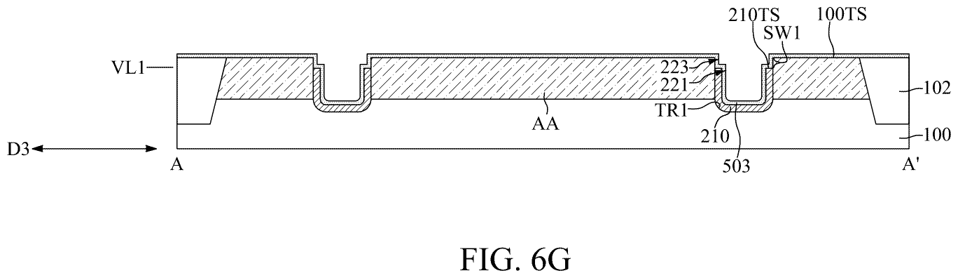

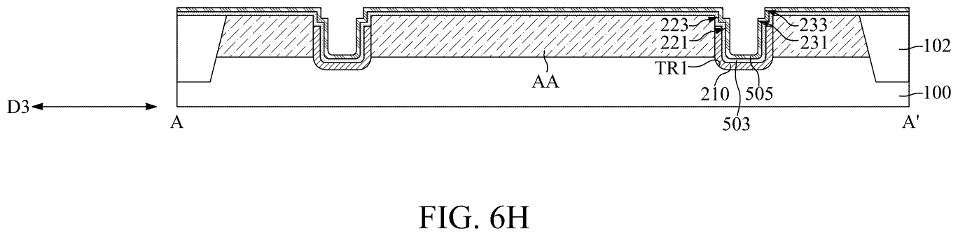

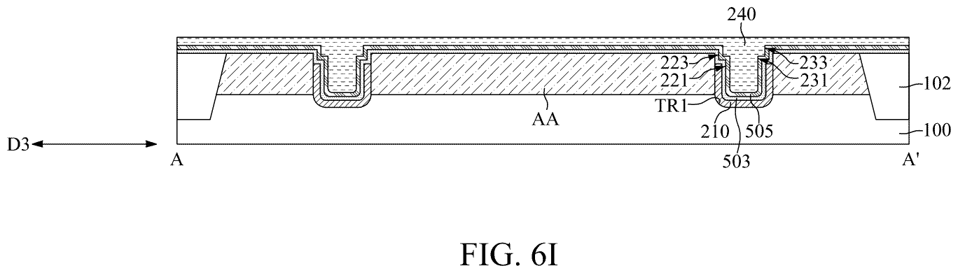

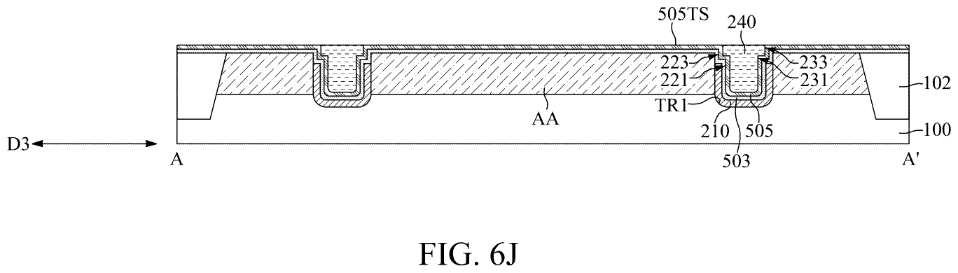

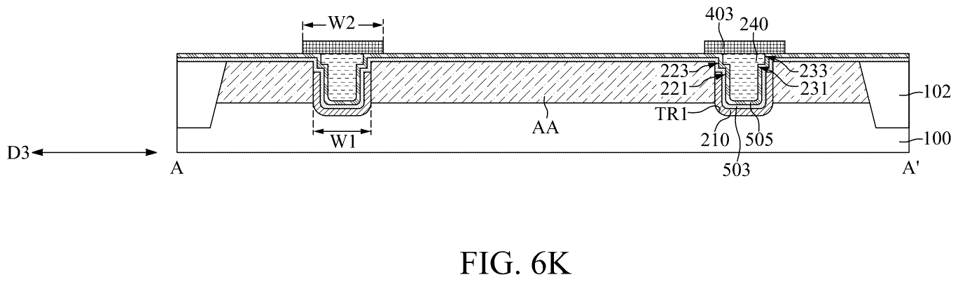

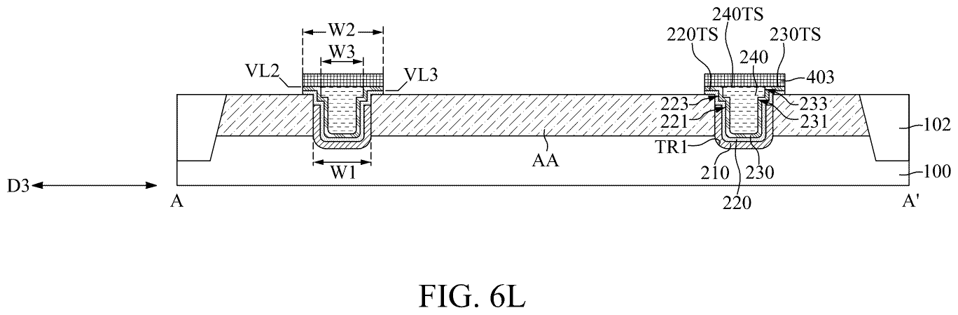

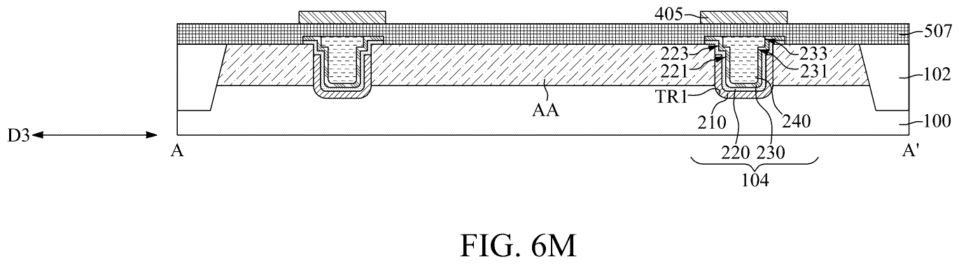

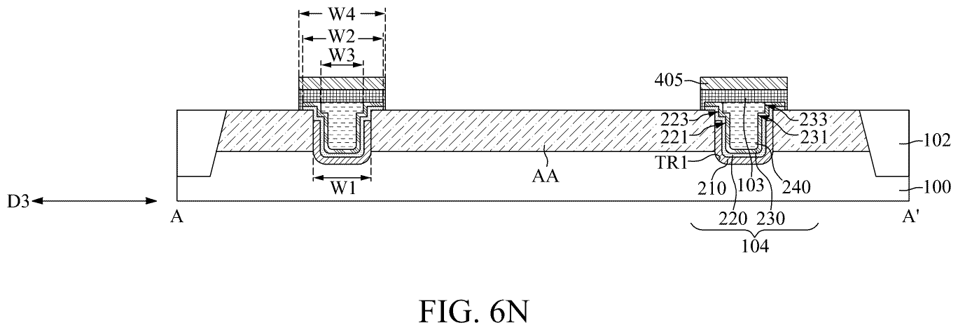

Referring to FIGS. 2 and 3B, step S15 is performed, wherein the recess gate structures 104 are formed in the substrate 100. As described with reference to FIGS. 1A and 1B, the recess gate structures 104 may be respectively formed in a line shape, wherein the line intersects the active regions AA. In addition, the recess gate structures 104 may respectively include the first insulating layer 210, the first assisting layer 220, the second assisting layer 230, the first filler layer 240 (i.e., the word line WL) and the capping dielectric layer 103. In some embodiments, a method in accordance with step S15 for forming the recess gate structures 104 may include steps S151, S153, S155 and S157 as shown in FIG. 5. Descriptions of steps S151, S153, S155 and S157, in association with intermediate stages illustrated in FIGS. 6A to 6N, are described below.

Referring to FIGS. 2 and 3C, step S17 is performed, wherein at least one dielectric layer 110 is formed on the substrate 100. For example, two dielectric layers 110 including a dielectric layer 110a and a dielectric layer 110b are formed on the substrate 100. In some embodiments, a method for forming the dielectric layers 110a and 110b includes a deposition process (e.g., a CVD process).

Referring to FIGS. 2 and 3D, step S19 is performed, wherein the bit line contacts BC are formed in the previously-formed dielectric layer(s) 110 (e.g., the dielectric layers 110a and 110b). In some embodiments, the bit line contacts BC may each include the conductive column 114 and the barrier layer 112. In such embodiments, a method for forming the bit line contacts BC may include forming via holes in the dielectric layer(s) 110 (e.g., the dielectric layers 110a and 110b) by a lithography process and an etching process (e.g., an anisotropic etching process). Subsequently, the barrier layers 112 are conformally formed in the via holes by a deposition process (e.g., a CVD process), and the conductive columns 114 are further deposited in the via holes by another deposition process (e.g., a CVD process) or a plating process. For example, the plating process described in the present disclosure may include an electroplating process or an electro-less plating process. In addition, a planarization process may be performed to remove materials of the conductive columns 114 and the barrier layers 112 outside the via holes.

Referring to FIGS. 2 and 3E, step S21 is performed, wherein the bit lines BL and an additional dielectric layer 110 (e.g., a dielectric layer 110c) are formed on the current structure. In some embodiments, a method for forming the bit lines BL may include forming trenches in the dielectric layer 110c, and depositing a conductive material into the trenches by a deposition process (e.g., a PVD process), a plating process, or a combination thereof. In addition, a planarization process may be performed to remove portions of the conductive material above the dielectric layer 110c, and remaining portions of the conductive material form the bit lines BL.

Referring to FIGS. 2 and 3F, step S23 is performed, wherein the capacitor contacts CC are formed in the dielectric layers 110 (e.g., the dielectric layers 110a to 110c). In some embodiments, a method for forming the capacitor contacts CC is similar to the method for forming the bit line contacts BC, except that deeper via holes are formed for accommodating the capacitor contacts CC.

Referring to FIGS. 2 and 3G, step S25 is performed, wherein the first and second conductive layers 108 and 120 are globally formed on the current structure. In other words, the capacitor contacts CC, the bit lines BL and the current topmost dielectric layer 110 (e.g., the dielectric layer 110c) may be covered by the first and second conductive layers 108 and 120. The second conductive layer 120 is stacked on the first conductive layer 108. The conductive pillars 116 and the landing pads CP will be formed by patterning the first and second conductive layers 108 and 120 in subsequent steps. In some embodiments, the first conductive layer 108 has a thickness greater than a thickness of the second conductive layer 120. In addition, in some embodiments, a conductive material for forming the second conductive layer 120 has a resistivity lower than a resistivity of the conductive material for forming the first conductive layer 108, and the conductive material for forming the first conductive layer 108 has a suitable etch resistance compared to that of the conductive material for forming the second conductive layer 120. A method for forming each of the first and second conductive layers 108 and 120 may include a deposition process (e.g., a PVD process), a plating process or a combination thereof.

Referring to FIGS. 2 and 3H, step S27 is performed, wherein the first and second conductive layers 108 and 120 are patterned to form initial conductive pillars 116′ and the landing pads CP. During such patterning, portions of the first and second conductive layers 108 and 120 are removed, and the bit lines BL as well as portions of the current topmost dielectric layer 110c may be exposed. Sidewalls of the formed initial conductive pillars 116′ may be substantially coplanar with sidewalls of the formed landing pads CP. In other words, a footprint area of each initial conductive pillar 116′ may be substantially identical to a footprint area of the overlying landing pad CP. The conductive pillars 116 will be formed by laterally recessing the initial conductive pillars 116′ in a subsequent step. In some embodiments, a method for forming the initial conductive pillars 116′ and the landing pads CP may include a lithography process and a first etching process, wherein the first etching process may be a single etching process (e.g., a single anisotropic etching process) or may include two etching processes (e.g., two anisotropic etching processes). When the first etching process is a single etching process, the first and second conductive layers 108 and 120 are partially removed in the same etching process.

Referring to FIGS. 2 and 3I, step S29 is performed, wherein the initial conductive pillars 116′ are laterally recessed, so as to form the conductive pillars 116. In some embodiments, a method for laterally recessing the initial conductive pillars 116′ includes a second etching process, such as an isotropic etching process (e.g., a wet etching process). In the embodiments where the conductive material for forming the landing pads CP has a suitable etch resistance compared to that of the conductive material for forming the initial conductive pillars 116′, damage to the landing pads CP may be avoided (or the landing pads CP may be only slightly consumed) during such isotropic etching process. As a consequence, the formed conductive pillars 116 can be laterally recessed with respect to the landing pads CP. In addition, in some embodiments, the conductive material for forming the bit lines BL has a suitable etch resistance compared to that of the conductive material for forming the initial conductive pillars 116′, and the bit lines BL may be undamaged (or only slightly consumed) during the isotropic etching process.

Referring to FIGS. 2, 3J and 4, step S31 is performed, wherein another dielectric layer 110 (e.g., the dielectric layer 110d) is formed. The conductive pillars 116 and the landing pads CP form stacking structures T on the capacitor contacts CC, and define recesses in between. The dielectric layer 110d is deposited in the recesses defined by the stacking structures T. In some embodiments, a method for forming the dielectric layer 110d includes a deposition process (e.g., a CVD process), and may further include a planarization process for removing excess material above the landing pads CP. As shown in FIGS. 3 and 4, in some embodiments, a width of the recess between adjacent stacking structures T arranged along a column direction (i.e., the direction D2) is much less than a width of the recess between adjacent stacking structures T arranged along an extending direction of the active regions AA (i.e., the direction D3). As shown in FIG. 4, the dielectric layer 110d may not fill the narrow recesses arranged along the column direction (i.e., the direction D2). Since the conductive pillars 116 are laterally recessed from the landing pads CP, a distance between adjacent landing pads CP is less than a distance between adjacent conductive pillars 116. In other words, the recesses defined between the stacking structures T respectively have a relatively narrow top portion and a relatively wide bottom portion. When the dielectric layer 110d is deposited in the narrow recesses (i.e., the recesses arranged along the direction D2), the relatively narrow top portions of such recesses may be sealed before the relatively wide bottom portions of the recesses can be filled. As a consequence, the air gaps AG may be formed in the relatively wide bottom portions. In other words, the possibly-formed air gaps AG are located between the conductive pillars 116 arranged along the column direction (i.e., the direction D2). As dimensions of the recesses, deposition conditions, and other parameters vary, the air gaps AG may be formed in different shapes, and top ends of the air gaps AG may or may not extend above top ends of the conductive pillars 116.

In some embodiments, the air gaps AG may not expose sidewalls of the conductive pillars 116 or top surfaces of the bit lines BL. In alternative embodiments, some portions of the conductive pillars 116 and/or some portions of the bit lines BL may be exposed by the air gaps AG.

Referring to FIGS. 2 and 3K, step S33 is performed, wherein the capacitor plugs PG and another dielectric layer 110 (e.g., the dielectric layer 110e) are formed on the current structure. The dielectric layer 110e is formed on the dielectric layer 110d and the landing pads CP, and the capacitor plugs PG penetrate through the dielectric layer 110e to establish an electrical connection with the landing pads CP. In some embodiments, a dielectric material layer may be globally formed on the dielectric layer 110d and the landing pads CP by a deposition process (e.g., a CVD process), and through holes are then formed in the dielectric material layer by a lithography process and an etching process (e.g., an anisotropic etching process), to form the dielectric layer 110e. Subsequently, a conductive material is deposited in the through holes by a deposition process (e.g., a PVD process), a plating process, or a combination thereof, and a planarization process may be performed to remove portions of the conductive material over the dielectric layer 110e. Remaining portions of the conductive material form the capacitor plugs PG.

Referring to FIGS. 2 and 3L, step S35 is performed, wherein one more dielectric layer 110 (e.g., the dielectric layer 110f) is formed on the current structure. The dielectric layer 110f is formed on the dielectric layer 110e, and has openings overlapping the capacitor plugs PG. In some embodiments, such openings further overlap portions of the dielectric layer 110e surrounding the capacitor plugs PG. In some embodiments, a dielectric material layer may be globally formed on the dielectric layer 110e and the capacitor plugs PG by a deposition process (e.g., a CVD process), and the openings (as shown in FIG. 3L) are then formed in the dielectric material layer by a lithography process and an etching process (e.g., an anisotropic etching process), to form the dielectric layer 110f.

Referring to FIGS. 2 and 3M, step S37 is performed, wherein the bottom electrodes BE are formed on the exposed capacitor plugs PG. The bottom electrodes BE are conformally formed in the openings of the dielectric layer 110f, and are separated from one another. Accordingly, the bottom electrodes BE cover the capacitor plugs PG, and establish an electrical connection with the capacitor plugs PG. In embodiments where the openings of the dielectric layer 110f further overlap portions of the dielectric layer 110e surrounding the capacitor plugs PG, such portions of the dielectric layer 110e are covered by the bottom electrodes BE. In some embodiments, a conductive material layer is conformally formed to cover surfaces of the dielectric layer 110f as well as exposed surfaces of the capacitor plugs PG and the dielectric layer 110e. Next, a planarization process is performed to remove portions of the conductive material layer over the dielectric layer 110f. Remaining portions of the conductive material layer form the bottom electrodes BE.

Referring to FIGS. 2 and 3N, step S39 is performed, wherein the dielectric layer DL and the top electrode TE are sequentially formed on the current structure. The dielectric layer DL conformally covers exposed surfaces of the dielectric layer 110f and the bottom electrodes BE. The top electrode TE fills the openings of the dielectric layer 110f, and covers a top surface of the dielectric layer DL. In some embodiments, the dielectric layer DL and the top electrode TE are globally formed.

In such embodiments, the storage capacitors SC share the same dielectric layer DL and the same top electrode TE, but include separate bottom electrodes BE. A method for forming the dielectric layer DL may include a deposition process (e.g., a CVD process), while a method for forming the top electrode TE may include a deposition process (e.g., a PVD process), a plating process or a combination thereof.

FIG. 5 is a flow diagram illustrating a manufacturing method of a recess gate structure in accordance with step S15 in FIG. 2. FIGS. 6A to 6N are schematic cross-sectional views of intermediate structures of the semiconductor device in accordance with the method in FIG. 5.

Referring to FIG. 5 and FIGS. 6A to 6C, step S151 is performed, wherein a substrate 100 may be provided and a first trench TR1 may be formed in the substrate 100.

With reference to FIG. 6A, the substrate 100 may include a bulk semiconductor substrate that is composed of at least one semiconductor material. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or a combination thereof.

In some embodiments, the substrate 100 may include a semiconductor-on-insulator structure that consists of, from bottom to top, a handle substrate, an insulator layer, and a topmost semiconductor material layer. The handle substrate and the topmost semiconductor material layer may be formed of a same material as the bulk semiconductor substrate mentioned above. The insulator layer may be a crystalline or non-crystalline dielectric material such as an oxide and/or a nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide, silicon nitride and/or boron nitride. The insulator layer may have a thickness between about 10 nm and about 200 nm. The insulator layer may eliminate leakage current between adjacent elements in the substrate 100 and reduce parasitic capacitance associated with source/drain terminals.

In some embodiments, the substrate 100 may include an active region AA. The active region AA is a region of the substrate 100. In some embodiments, the active region AA of the substrate 100 is a region doped with a first conductive type (e.g., n-type) dopants or doped with a second conductive type (e.g., p-type) dopants, wherein the second conductive type is complementary to the first conductive type.

The active regions AA are electrically isolated from one another by the isolation structure 102. In some embodiments, the isolation structure 102 is formed in a recess at a surface of the substrate 100, and is made of an insulating material. In such embodiments, the isolation structure 102, which may also be referred to as a trench isolation structure, extends from the surface of the substrate 100 into the substrate 100. A depth of the isolation structure 102 may be greater than a depth of the active region AA, and the active regions AA are laterally separated from one another by the isolation structure 102. It should be noted that the isolation structure 102 extends between the active regions AA, and what appear in FIG. 6A to be multiple portions of the isolation structure 102 may actually be connected to one another.

With reference to FIG. 6A, a first mask layer 401 may be deposited over the substrate 100. In some embodiments, the first mask layer 401 may be deposited by performing a spin-coating process on the substrate 100. The first mask layer 401 may be configured to be a mask layer to prevent the layer underneath from subsequent etching process. The first mask layer 401 may be patterned by a photolithography process. The first mask layer 401 may be exposed to process light according to a mask (not shown in FIG. 6A). A wavelength of the process light may be associated with a critical dimension of the first trench TR1. In some embodiments, the process light may be a deep ultraviolet (DUV). In some embodiments, the process light may be an extreme ultraviolet (EUV), and the photolithography process may be an EUV lithography. After exposing the first mask layer 401 to the process light, a pattern on the mask is converted to the first mask layer 401. The first mask layer 401 may be then etched according to the converted pattern so as to form the pattern on the first mask layer 401.

With reference to FIG. 6B, a portion of the substrate 100 may be etched according to the first mask layer 401 to form the first trench TR1. In some embodiments, the substrate 100 may be etched by performing a dry etch process such as a reactive ion etching (RIE). The first mask layer 401 may be removed and the first trench TR1 may be formed.

With reference to FIG. 5 and FIGS. 6C to 6E, in step S153, a first insulating layer 210 may be conformally formed in the first trench TR1.

With reference to FIG. 6C, a layer of first insulating material 501 may be conformally formed in the first trench TR1 and on the top surface 100TS of the substrate 100. In some embodiments, the layer of first insulating material 501 may have a thickness in a range of about 1 nm to about 7 nm, such as about 1 nm, about 2 nm, about 3 nm, about 4 nm, about 5 nm, about 6 nm, or about 7 nm. In some embodiments, the first insulating material 501 may be, for example, a high-k material, an oxide, a nitride, an oxynitride, or a combination thereof. In some embodiments, the layer of first insulating material 501 may be formed by a thermal oxidation process. For example, the layer of first insulating material 501 may be formed by oxidizing the surface of the first trench TR1 and the top surface 100TS of the substrate 100. In some embodiments, the layer of first insulating material 501 may be formed by a deposition process such as a chemical vapor deposition or an atomic layer deposition. In some embodiments, after a liner polysilicon layer (not shown for clarity) is deposited, the layer of first insulating material 501 may be formed by radical-oxidizing the liner polysilicon layer. In some embodiments, after a liner silicon nitride layer (not shown for clarity) is formed, the layer of first insulating material 501 may be formed by radical-oxidizing the liner silicon nitride layer.

In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide, or a combination thereof.

With reference to FIG. 6C, a first sacrificial layer 407 may be deposited over the layer of first insulating material 501. The first sacrificial layer 407 may have a T-shape to fill the first trench TR1 and may cover the layer of first insulating material 501. In some embodiments, the first sacrificial layer 407 may include a material having an etch resistance less than that of the first insulating material 501. In some embodiments, the first sacrificial layer 407 may be a photoresist layer.

With reference to FIG. 6D, in some embodiments, the first sacrificial layer 407 may be etched to form a recess. In detail, the first sacrificial layer 407 may be etched to a vertical level VL1 lower than the top surface 100TS of the substrate 100. In some embodiments, a planarization process may be performed until the top surface 100TS of the substrate 100 is exposed to remove excess material and provide a substantially flat surface for subsequent processing steps. Next, a recessing process may be performed to remove portions of the first sacrificial layer 407. In some embodiments, a ratio of an etch rate of the first sacrificial layer 407 to an etch rate of the first insulating material 501 may be between about 100:1 and about 1.05:1, between about 15:1 and about 2:1, or between about 10:1 and about 2:1 during the recessing process.

With reference to FIG. 6E, an etch-back process may be performed to remove portions of the first insulating material 501. In some embodiments, a ratio of an etch rate of the first insulating material 501 to an etch rate of the first sacrificial layer 407 may be between about 100:1 and about 1.05:1, between about 15:1 and about 2:1, or between about 10:1 and about 2:1 during the etch-back process. In some embodiments, a ratio of the etch rate of the first insulating material 501 to an etch rate of the substrate 100 may be between about 100:1 and about 1.05:1, between about 15:1 and about 2:1, or between about 10:1 and about 2:1 during the etch-back process. After the etch-back process is performed, the remaining first insulating material 501 may be referred to as the first insulating layer 210. The top surface 210TS of the first insulating layer 210 may be at the vertical level VL1 lower than the top surface 100TS of the substrate 100.

With reference to FIG. 6F, a removal process may be performed to completely remove the first sacrificial layer 407. In some embodiments, the removal process may be an ashing process when the first sacrificial layer 407 is a photoresist layer. In some embodiments, the removal process may be an etching process such as a wet etching process. In some embodiments, a ratio of a removal rate of the first sacrificial layer 407 to a removal rate of the first insulating layer 210 may be between about 100:1 and about 1.05:1, between about 15:1 and about 2:1, or between about 10:1 and about 2:1 during the removal process. In some embodiments, a ratio of a removal rate of the first sacrificial layer 407 to a removal rate of the substrate 100 may be between about 100:1 and about 1.05:1, between about 15:1 and about 2:1, or between about 10:1 and about 2:1 during the removal process.

With reference to FIG. 5 and FIGS. 6G to 6L, in step S155, a first assisting layer 220 may be conformally formed on the first insulating layer 210, a second assisting layer 230 may be conformally formed on the first assisting layer 220, and a first filler layer 240 may be formed on the second assisting layer 230.

With reference to FIG. 6G, a layer of first assisting material 503 may be conformally formed on the first insulating layer 210, on an exposed portion SW1 of the first trench TR1, and on the top surface 100TS of the substrate 100. In some embodiments, the layer of first assisting material 503 may include a first step portion 221 and a second step portion 223. The first step portion 221 may be formed adjacent to the top surface 210TS of the first insulating layer 210. The second step portion 223 may be formed adjacent to a corner configured by the exposed portion SW1 of the first trench TR1 and the top surface 100TS of the substrate 100. In some embodiments, the first assisting material 503 may be, for example, manganese. The layer of first assisting material 503 may be formed by, for example, atomic layer deposition or another applicable deposition process.

With reference to FIG. 6H, a layer of second assisting material 505 may be conformally formed on the layer of first assisting material 503. In some embodiments, the layer of second assisting material 505 may include a first step portion 231 and a second step portion 233. The first step portion 231 may cover the first step portion 221. The second step portion 233 may cover the second step portion 223. In some embodiments, the second assisting material 505 may be, for example, titanium silicon nitride. In some embodiments, a titanium content in the second assisting material 505 may be about 10 to 40 atomic percent. A silicon content in the second assisting material 505 may be about 10 to 40 atomic percent. A nitrogen content in the second assisting material 505 may be about 25 to 47 atomic percent.

In some embodiments, the layer of second assisting material 505 may be formed by a thermal chemical vapor deposition process. During the thermal chemical vapor deposition process, a titanium-containing gas, a silicon-containing gas, and a nitrogen-containing gas may be introduced to the layer of first assisting material 503 to form a titanium silicon nitride film (i.e., the layer of second assisting material 505). The titanium-containing gas may be, for example, tetraxydimethylaminotitanium or tetraxydiethylaminotitanium. The silicon-containing gas may be, for example, SiH₂Cl₂, SiHCl₃, SiCl₄, SiH₄, or Si₂H₆. The nitrogen-containing gas may be, for example, ammonia or monomethylhydrazine. A flow rate of the titanium-containing gas may be between about 5 standard cubic centimeters per minute (sccm) and about 50 sccm. A flow rate of the silicon-containing gas may be between about 5 sccm and about 500 sccm. A flow rate of the nitrogen-containing gas may be between about 50 sccm and about 500 sccm. A process pressure of the thermal chemical vapor deposition process may be between about 0.3 Torr and about 5 Torr. A process temperature may be between about 400° C. and about 650° C.

Alternatively, in some embodiments, the layer of second assisting material 505 may be formed by a plasma chemical vapor deposition process. A gas for generating plasma may comprise, for example, hydrogen and argon. A frequency of radio-frequency power of the plasma may be 13.56 MHz. The radio-frequency power of the plasma may be between about 200 W and about 800 W. A flow rate of the titanium-containing gas (e.g., TiCl₄) may be between about 1 sccm and about 10 sccm. A flow rate of the silicon-containing gas (e.g., SiH₄) may be between about 0.1 sccm and about 10 sccm. A flow rate of the nitrogen-containing gas (N₂) may be between about 30 sccm and about 500 sccm. A flow rate of hydrogen may be between about 100 and about 3000 sccm. A flow rate of argon may be between about 100 and about 2000 sccm. A process pressure of the plasma chemical vapor deposition process may be between about 0.5 Torr and about 5 Torr. A process temperature may be between about 350° C. and about 450° C.

Alternatively, in some embodiments, a layer of titanium nitride and a layer of silicon nitride may be sequentially formed on the layer of first assisting material 503. An annealing process may be performed to turn the layer of titanium nitride and the layer of silicon nitride into a titanium silicon nitride film (i.e., the layer of second assisting material 505).

With reference to FIG. 6I, a first filler layer 240 may be formed on the layer of second assisting material 505 and may completely fill the first trench TR1. Stated differently, the first filler layer 240 may have a T-shaped cross-sectional profile in the current stage. In some embodiments, the first filler layer 240 may be formed of, for example, aluminum, tungsten, copper, or a combination thereof. In some embodiments, the first filler layer 240 may be formed by, for example, chemical vapor deposition, physical vapor deposition, electroplating, electroless plating, or other applicable deposition process.

With reference to FIG. 6J, a planarization process, such as chemical mechanical polishing, may be performed, until the top surface 505TS of the layer of second assisting material 505 is exposed, to remove excess material and provide a substantially flat surface for subsequent processing steps.

With reference to FIG. 6K, a second mask layer 403 may be formed on the first filler layer 240 and may cover a portion of the layer of second assisting material 505. A width W1 of the first insulating layer 210 may be less than a width W2 of the second mask layer 403. In some embodiments, the second mask layer 403 may be a photoresist layer. The pattern of the second mask layer 403 may be formed with a procedure similar to that of the first mask layer 401 illustrated in FIG. 6A, and descriptions thereof are not repeated herein.

With reference to FIG. 6L, an etching process may be performed to remove portions of the second assisting material 505 and the first assisting material 503. The etching process may be a multi-staged etching process. For example, the etching process may be a two-staged anisotropic dry etching process. An etching chemistry may be different for each stage to provide different etching selectivities. In some embodiments, a ratio of an etch rate of the second assisting material 505 to an etch rate of the first assisting material 503 may be between about 100:1 and about 1.05:1, between about 15:1 and about 2:1, or between about 10:1 and about 2:1 during the first stage of the etching process. In some embodiments, a ratio of the etch rate of the first assisting material 503 to the etch rate of the second assisting material 505 may be between about 100:1 and about 1.05:1, between about 15:1 and about 2:1, or between about 10:1 and about 2:1 during the second stage of the etching process. In some embodiments, a ratio of the etch rate of the first assisting material 503 to an etch rate of the substrate 100 may be between about 100:1 and about 1.05:1, between about 15:1 and about 2:1, or between about 10:1 and about 2:1 during the second stage of the etching process.

After the etching process is performed, the remaining first assisting material 503 may be turned into the first assisting layer 220. The first assisting layer 220 may be conformally formed on the first insulating layer 210 and may include a U-shaped cross-sectional profile including the first step portion 221 and the second step portion 223. The remaining second assisting material 505 may be turned into the second assisting layer 230. The second assisting layer 230 may be conformally formed on the first assisting layer 220 and may include a U-shaped cross-sectional profile including the first step portion 231 and the second step portion 233. The top surface 230TS of the second assisting layer 230 and the top surface 240TS of the first filler layer 240 may be substantially coplanar. The top surface 230TS of the second assisting layer 230 or the top surface 240TS of the first filler layer 240 may be at a vertical level VL2 higher than a vertical level VL3 of the top surface 220TS of the first assisting layer 220. The second mask layer 403 may be removed after the first assisting layer 220 and the second assisting layer 230 are formed.

With reference to FIG. 6L, in some embodiments, the first assisting layer 220 and the second assisting layer 230 may have the same width W2. In some embodiments, the width W1 of the first insulating layer 210 may be less than the width W2 of the first assisting layer 220 or less than the width W2 of the second assisting layer 230. In some embodiments, a width W3 of the first filler layer 240 may be less than the width W1 of the first insulating layer 210 or less than the width W2 of the first assisting layer 220.

With reference to FIGS. 5, 6M, and 6N, in step S157, a capping dielectric layer 103 may be formed to cover the first assisting layer 220, the second assisting layer 230, and the first filler layer 240.

With reference to FIG. 6M, a layer of second insulating material 507 may be formed to cover the first assisting layer 220, the second assisting layer 230, and the first filler layer 240. In some embodiments, the second insulating material 507 may be, for example, silicon oxide, silicon nitride, silicon oxynitride, silicon nitride oxide, or other applicable insulating materials.

It should be noted that, in the description of the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

With reference to FIG. 6M, a third mask layer 405 may be formed on the layer of second insulating material 507. In some embodiments, the third mask layer 405 may be a photoresist layer and may include the pattern of the capping dielectric layer 103.

With reference to FIG. 6N, an etching process may be performed using the third mask layer 405 as the mask to remove portions of the second insulating material 507. In some embodiments, a ratio of an etch rate of the second insulating material 507 to an etch rate of the substrate 100 may be between about 100:1 and about 1.05:1, between about 15:1 and about 2:1, or between about 10:1 and about 2:1 during the etching process. The remaining second assisting material 505 may be referred to as the capping dielectric layer 103. After the capping dielectric layer 103 is formed, the third mask layer 405 may be removed.

With reference to FIG. 6N, in some embodiments, a width W4 of the capping dielectric layer 103 may be greater than the width W1 of the first insulating layer 210. In some embodiments, the width W4 of the capping dielectric layer 103 may be greater than the width W2 of the first assisting layer 220 or the width W2 of the second assisting layer 230. In some embodiments, the width W4 of the capping dielectric layer 103 may be greater than the width W3 of the first filler layer 240.

In some embodiments, the first insulating layer 210, the first assisting layer 220, the second assisting layer 230, the first filler layer 240, and the capping dielectric layer 103 may together configure a gate structure.

In accordance with the descriptions above, the semiconductor device 10 has been formed by a manufacturing method according to some embodiments of the present disclosure. Moreover, the semiconductor device 10 may be subjected to further manufacturing processes and/or testing processes.

As described above, the semiconductor device according to embodiments of the present disclosure includes memory cells arranged as an array. Each memory cell includes a transistor and storage capacitor connected to the transistor. A conductive pillar and a landing pad are disposed between one of the storage capacitors and an active region of the transistor connected to such storage capacitor. The landing pad is disposed on the conductive pillar, and a sidewall of the conductive pillar is recessed from a sidewall of the landing pad. Therefore, a distance between the landing pads of adjacent memory cells is less than a distance between the conductive pillars of adjacent memory cells. As a result, while a dielectric material is being deposited between stacking structures (each of which includes a conductive pillar and the overlying landing pad), a space between adjacent landing pads may be sealed before a space between adjacent conductive pillars is filled. Consequently, air gaps may be formed between the conductive pillars. Due to a low dielectric constant of air sealed in the air gaps, a parasitic capacitance between the conductive pillars can be reduced by the formation of the air gaps, thus effectively reducing an RC delay of the semiconductor device. As a result, an operation speed of the semiconductor device can be improved. In embodiments where a resistivity of the landing pads is less than a resistivity of the conductive pillars, a parasitic capacitance between the landing pads may be limited, even though the space between the landing pads is narrower than the space between the conductive pillars.

In an aspect of the present disclosure, a memory device is provided. The memory device comprises: a substrate having an active region; a recess gate structure disposed in the substrate and intersecting the active region; a conductive pillar disposed over the substrate and electrically connected to the active region; a landing pad disposed on the conductive pillar and electrically connected to the conductive pillar; and a stack of dielectric layers disposed over the substrate and laterally surrounding the conductive pillar and the landing pad.

In another aspect of the present disclosure, a memory device is provided. The memory device comprises: a first insulating layer concavely disposed in a substrate and comprising a U-shaped cross-sectional profile; a first assisting layer conformally disposed on the first insulating layer and the substrate; a first filler layer disposed on the first assisting layer; a second assisting layer conformally positioned between the first assisting layer and the first filler layer; and a capping dielectric layer disposed on the substrate and covering the first assisting layer and the first filler layer.

In another aspect of the present disclosure, a method for fabricating a semiconductor device is provided. The method comprises: forming an active region in a substrate; forming a recess gate structure in the substrate, wherein the recess gate structure intersects the active region; forming at least one dielectric layer on the substrate; forming a bit line contact in the at least one dielectric layer; forming a bit line over the bit line contact and in an additional dielectric layer; forming a contact structure on the substrate, wherein the contact structure is formed at a side of the recess gate structure, and wherein the contact structure is electrically connected to the active region; sequentially forming a first conductive layer and a second conductive layer over the substrate, wherein the contact structure is covered by the first and second conductive layers; forming a conductive pillar and a landing pad over the substrate, wherein the conductive pillar overlaps and electrically connects to the contact structure, the landing pad covers and electrically connects to the conductive pillar, and a sidewall of the conductive pillar is laterally recessed from a sidewall of the landing pad; and forming a dielectric layer to laterally surround the conductive pillar and the landing pad.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a first insulating layer concavely disposed in a substrate and comprising a U-shaped cross-sectional profile;
a first assisting layer conformally disposed on the first insulating layer and the substrate;
a first filler layer disposed on the first assisting layer;
a second assisting layer conformally positioned between the first assisting layer and the first filler layer; and
a capping dielectric layer disposed on the substrate and covering the first assisting layer and the first filler layer.

2. The semiconductor device of claim 1, wherein a top surface of the first insulating layer is at a vertical level lower than a top surface of the substrate.

3. The semiconductor device of claim 2, wherein the first assisting layer comprises a first step portion and a second step portion, wherein the first step portion of the first assisting layer is positioned adjacent to the top surface of the first insulating layer, and the second step portion of the first assisting layer is positioned adjacent to the top surface of the substrate.

4. The semiconductor device of claim 3, wherein the first assisting layer comprises manganese.

5. The semiconductor device of claim 4, wherein a width of the first assisting layer is greater than a width of the first insulating layer.

6. The semiconductor device of claim 5, wherein a width of the capping dielectric layer is greater than the width of the first assisting layer.

7. The semiconductor device of claim 6, wherein a width of the first filler layer is less than the width of the first insulating layer.

8. The semiconductor device of claim 7, wherein the second assisting layer comprises a first step portion and a second step portion, wherein the first step portion of the second assisting layer covers the first step portion of the first assisting layer, and the second step portion of the second assisting layer covers the second step portion of the first assisting layer.

9. The semiconductor device of claim 8, wherein the second assisting layer comprises titanium silicon nitride.

10. The semiconductor device of claim 9, wherein a width of the second assisting layer is substantially same as the width of the first assisting layer.

11. The semiconductor device of claim 10, wherein the first filler layer comprises copper, aluminum, tungsten, or a combination thereof.
